(19) United States
(12) Patent Application Publication
(10) Pub. No.: US 2008/0237854 A1
(43) Pub. Date: Oct. 2, 2008

(54) METHOD FOR FORMING CONTACT PADS

(76) Inventors: Ping-Chang Wu, Hsin-Chu Hsien (TW); Chieh-Ching Huang, Miaoli County (TW)

Correspondence Address: NORTH AMERICA INTELLECTUAL PROPERTY CORPORATION, P.O. BOX 506, MERRIFIELD, VA, 22116, US

(21) Appl. No.: 11/690,862

(22) Filed: Mar. 26, 2007

(51) Int. Cl. H01L 23/48

(52) U.S. Cl. 257/738

(57) ABSTRACT

First, a substrate having a conductor therein is provided. Next, a first dielectric layer is disposed on the conductor and the substrate and a first opening is formed in the first dielectric layer for exposing the conductor. A first metal layer is deposited over the surface of the first dielectric layer and into the first opening. Next, an etching stop layer and a second metal layer are deposited over the surface of the first metal layer, and a pattern transfer process is performed by using a second dielectric layer as a mask to remove a portion of the first metal layer, the etching stop layer, and the second metal layer for exposing the first dielectric layer. A passivation layer is disposed on the second metal layer and the first dielectric layer and a second opening is formed in the passivation layer to expose a portion of the second metal layer.

### BACKGROUND OF THE INVENTION

1. Field of the Invention

The invention relates to a method for fabricating contact pads on a semiconductor substrate.

2. Description of the Prior Art

In creating semiconductor devices, the technology of interconnecting devices and device features is a continuing challenge in the era of sub-micron devices. Contact pads are frequently used for this purpose, in which numerous efforts have been dedicated to provide contact pads that are reliable, simple, and effective.

Contact pads, having dimensions of between about 40×40 μm and 120×120 μm, are in current practice frequently used as access or input/output contact points during wafer level testing of semiconductor devices. During the entire phase of testing, these contact pads be contacted a number of times. Testing is typically performed at high speed, which frequently results in landing the test probe on the surface of the contact pad at high speed, resulting in mechanical damage to the surface of the contact pad. Testing is especially important for memory products. In order to increase the yield for memory products, a plurality of redundant cells is often prepared for repairing purpose. During the initial phase of memory testing, test probes are used to examine the quality of redundant cells. The cells that are of lower grade will be repaired by a laser repairing process, such that the repaired units will be prepared for more testing thereafter. Hence for memory products, a wafer is tested at least two times.

As described previously, during the phase of probe testing, the surface of the contact pad will be damaged frequently. Surface damage to the contact pad may occur in the form of a dent (in the surface of the contact pad) or may even become severe enough that the surface of the contact pad is disrupted, resulting in the occurrence of burring in the surface of the contact pad. After the probing process is completed, a portion of the contact pads will be used for bumping process or wire bonding processes, in which a plurality of bumps or wires will be formed on top of the contact pads for electrically connecting to other devices.

Please refer to FIG. 1 through FIG. 4. FIG. 1 through FIG. 4 illustrate a method for forming a contact pad according to the prior art. As shown in FIG. 1, a substrate (not shown) having a dielectric layer 12 thereon is provided. Next, a pattern transfer process and a deposition process are performed to form a conductor 14 in the dielectric layer 12. The conductor 14 is preferably a copper damascene conductor. Next, a dielectric layer 16 is disposed on the damascene conductor 14. A pattern transfer process is performed thereafter by using a patterned photoresist to form an opening 18 in the dielectric layer 16. As shown in FIG. 3, a metal layer 20 composed of aluminum or aluminum alloy is deposited over the surface of the dielectric layer 16 and into the opening 18. As shown in FIG. 4, another pattern transfer process is then performed to remove a portion of the metal layer 20 for forming a contact pad 22.

As shown in FIG. 5, a probing process can be performed by landing a test probe on the resulting contact pad 22 to verify the completion of the internal circuits. The surface of the contact pad 22 however, is often disrupted by the contact of the test probe during the probing process, as shown in the figure. After the probing process is completed, a bumping process or a wire bonding process can be performed on the contact pad. However, due to the fact that the contact pad 22 is composed of a single metal layer, the disrupted surface caused by the probing process will ultimately influence the quality of the bump and wire formed atop the contact pad, thereby reducing the reliability of the resulting device.

### SUMMARY OF THE INVENTION

It is an objective of the present invention to eliminate the effect of surface damage to the contact pads caused by probes for wafer level testing of semiconductor devices.

Accordingly, a method for forming a contact pad is disclosed. First, a substrate having a conductor therein is provided. Next, a first dielectric layer is disposed on the conductor and the substrate, and a first opening is formed in the first dielectric layer for exposing the conductor. Next, a first metal layer is deposited over the surface of the first dielectric layer and into the first opening. Next, an etching stop layer and a second metal layer are deposited over the surface of the first metal layer, and a pattern transfer process is performed by using a second dielectric layer as a mask to remove a portion of the first metal layer, the etching stop layer, and the second metal layer and expose the first dielectric layer. A passivation layer is disposed on the second metal layer and the first dielectric layer thereafter and a second opening is formed in the passivation layer to expose a portion of the second metal layer.

Another aspect of the present invention is to provide a contact pad structure. The contact pad structure includes a substrate having a conductor therein; a first dielectric layer disposed on the conductor and the substrate, wherein the first dielectric layer comprises a first opening for exposing the conductor; a first metal layer partially disposed over the surface of the first dielectric layer and in the first opening; an etching stop layer disposed on the first metal layer; a second metal layer disposed on the etching stop layer; and a passivation layer disposed on the first dielectric layer and the second metal layer, wherein the passivation layer comprises a second opening to expose a portion of the second metal layer.

Specifically, the contact pad of the present invention includes two metal layers and an etching stop layer therebetween. Preferably, the top metal layer and the etching stop layer can be used as a cushion for reducing the impact from the landing of a test probe during the probing process. After the probing process is completed, the top metal layer having probing tracks and disrupted surfaces and the etching stop layer are removed via an etching process to expose the bottom metal layer underneath. The exposed bottom metal layer can be used either for wire bonding or a bumping process thereafter. Since the top metal layer that carries all the damages resulted from the probing process is removed, the damage-free bottom metal layer will be able to ensure the reliability and quality of the bump and wire formed on the pad thereafter.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 5 illustrate a method for forming a contact pad according to the prior art.

FIG. 6 through FIG. 12 illustrate a method for forming a contact pad according to the preferred embodiment of the present invention.

FIG. 13 shows a perspective view of a contact pad after being tested by a test probe according to the present invention.

FIG. 14 shows a perspective view of a contact pad according to an embodiment of the present invention.

FIG. 15 shows a perspective view of a contact pad according to an embodiment of the present invention.

FIG. 16 illustrates a perspective view of forming a bump on a contact pad according to an embodiment of the present invention.

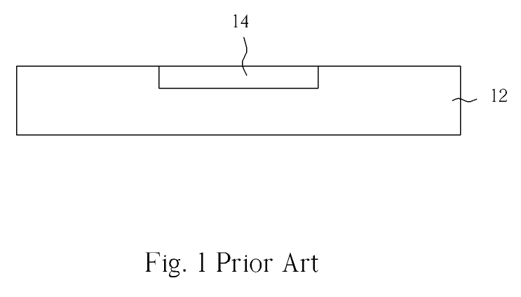

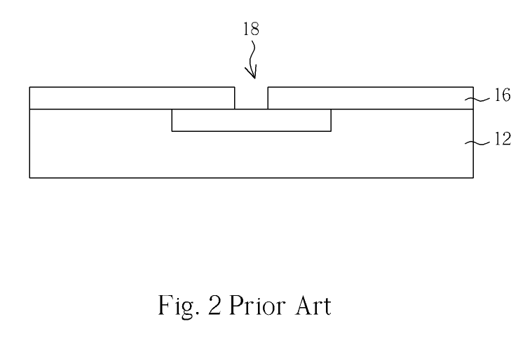

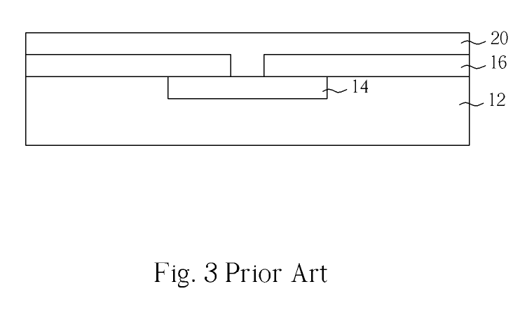

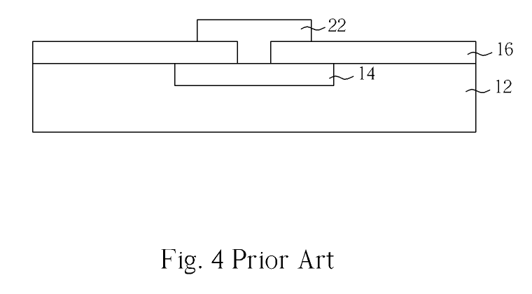

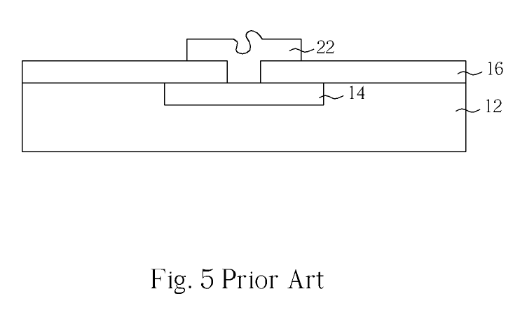

### DETAILED DESCRIPTION

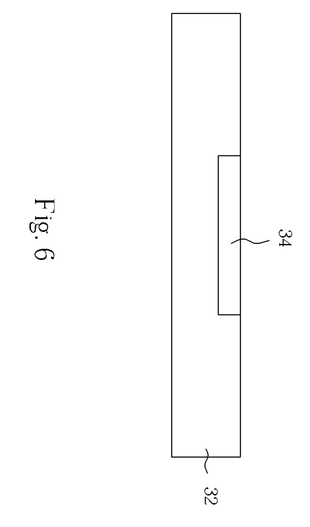

Please refer to FIG. 6 through FIG. 12. FIG. 6 through FIG. 12 illustrate a method for forming a contact pad according to the preferred embodiment of the present invention. As shown in FIG. 6, a substrate (not shown) having a dielectric layer 32 thereon is provided. Next, a pattern transfer process and a deposition process are performed to form a conductor 34 in the dielectric layer 32. The conductor 34 is preferably a copper damascene conductor. Specifically, the damascene conductor 34 is formed by first using a patterned mask to form an opening in the dielectric layer 32, depositing a copper layer over the surface of the dielectric layer 32 and into the opening, and performing a chemical mechanical polishing process to planarize the surface of the copper layer, such that the surface of the copper layer is exposed and even with the surface of the dielectric layer 32.

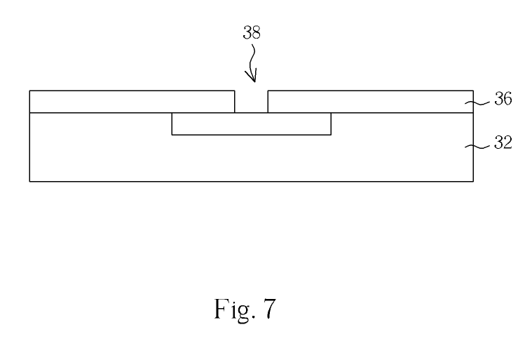

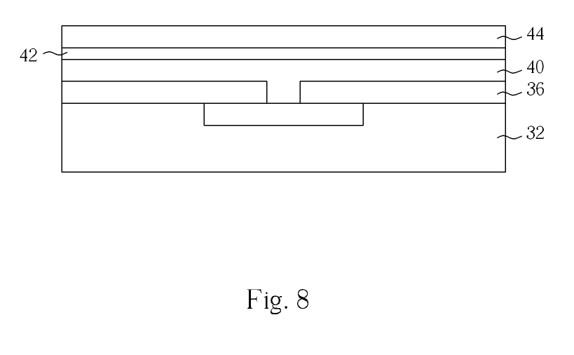

Next, as shown in FIG. 7, a first dielectric layer 36 is formed on the damascene conductor 34 and the dielectric layer 32, and a pattern transfer process is performed by using another patterned mask to form an opening 38 in the first dielectric layer 36. As shown in FIG. 8, a first metal layer 40 is deposited over the surface of the first dielectric layer 36 and into the opening 38. An etching stop layer 42 and a second metal layer 44 are disposed thereafter on the first metal layer 40. According to the preferred embodiment of the present invention, the first metal layer 40 and the second metal layer 44 are composed of aluminum, copper, tungsten, titanium, or a compound thereof, and the etching stop layer 42 is composed of titanium, tantalum, titanium nitride, tantalum nitride, or a compound thereof. The thickness of the second metal layer 44 is approximately between 5000 to 20000 angstroms, or preferably between 4000 to 12000 angstroms.

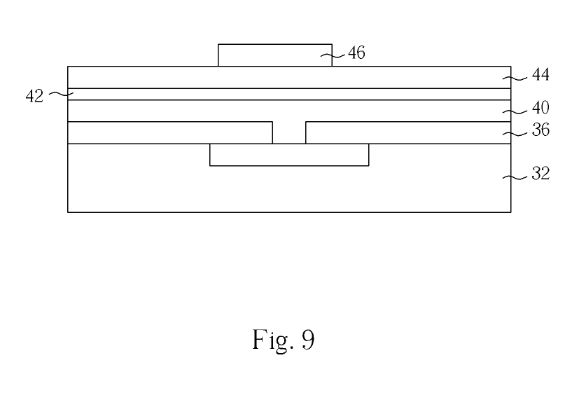

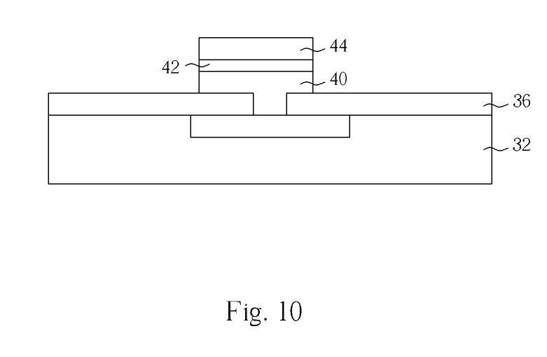

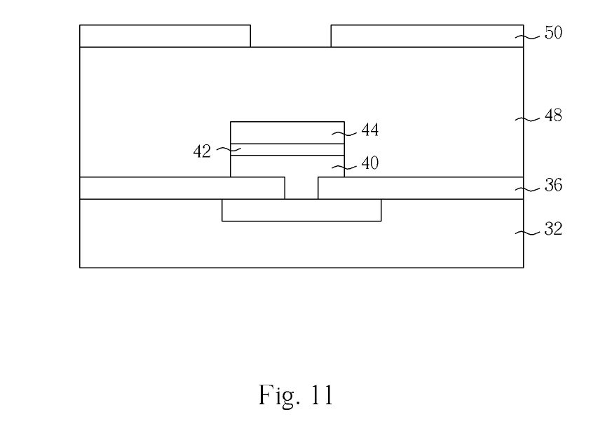

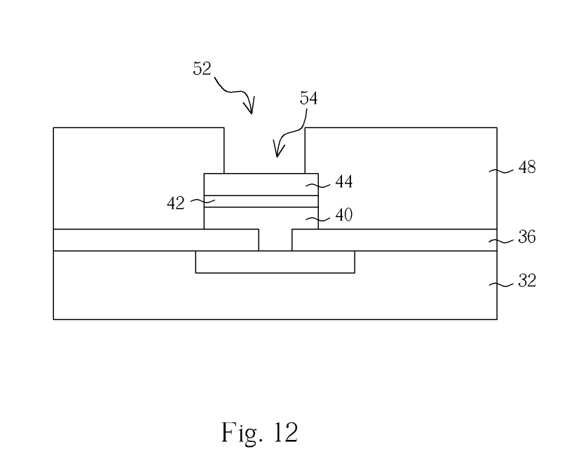

Next, a second dielectric layer 46 is disposed on the second metal layer 44, and a pattern transfer process is performed to remove a portion of the second dielectric layer 46, as shown in FIG. 9. As shown in FIG. 10, an etching process is performed by using the patterned second dielectric layer 46 as a mask to remove a portion of the second metal layer 44, the etching stop layer, 42, and the first metal layer 40. As shown in FIG. 11, a passivation layer 48 is deposited over the surface of the first dielectric layer 36 and the second metal layer 44 and a patterned mask, such as a patterned third dielectric layer 50 is disposed on the passivation layer 48 thereafter. As shown in FIG. 12, an etching process is performed by using the third dielectric layer 50 as a mask to form an opening 52 in the passivation layer 48 and exposes a portion of the second metal layer 44.

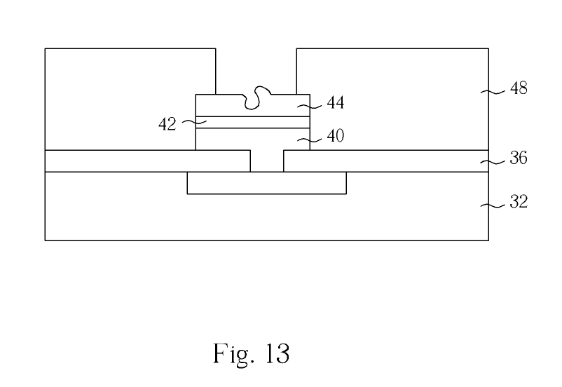

According to the preferred embodiment of the present invention, the resulting three layer structure composed of the first metal layer 40, the etching stop layer 42, and the second metal layer 44 ultimately constitutes a contact pad 54 for wafer level testing. Subsequently, a probing process can be performed by landing a test probe on the surface of the second metal layer 44 to test the electrical performance of the wafer. The probing process will typically damage or disrupt the surface of the contact pad, such as causing a dent shown in FIG. 13. Due to the fact that the second metal layer 44 has a depth of approximately 5000 to 20000 angstroms, the impact of the probing process can be absorbed by the second metal layer 44. In other words, the depth of the total impact caused by the probing process is less than the total thickness of the second metal layer 44 and the etching stop layer 42.

After the probing process is completed, an in-situ or an ex-situ etching process is performed by using the surrounding passivation layer 48 as a mask to remove a portion of the second metal layer 44. The etching process can either be a dry etching process, such as a plasma-enhanced etching process, or a wet etching process. The wet etching process typically involves the utilization of an etchant, such as a phosphoric acid solution. After a portion of the second metal layer 44 is removed, another etching process is performed by using hydrogen fluoride or regular cleaning agent (RCA) to remove a portion of the etching stop layer 42 for forming an opening 60. Preferably, the position of the opening 60 is formed with respect to the opening 52 formed in the passivation layer 48 previously.

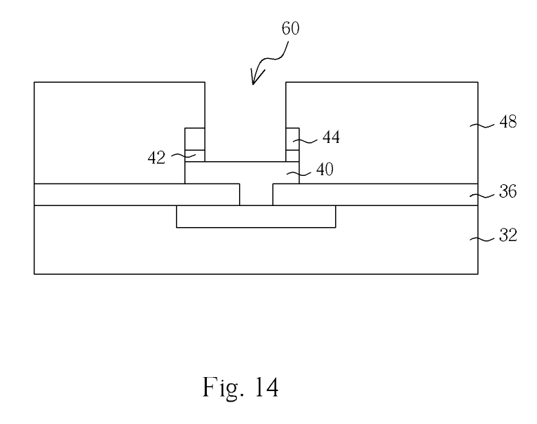

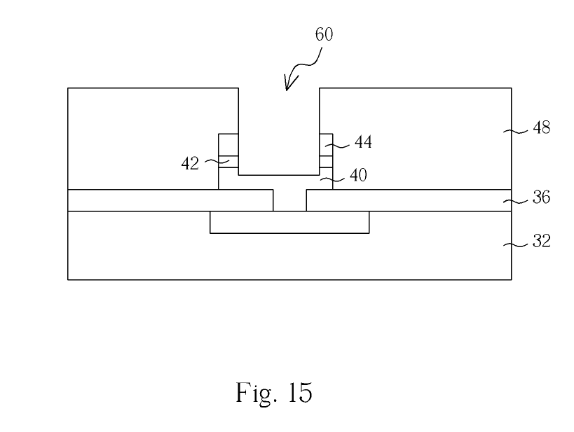

According to an embodiment of the present invention, the second metal layer 44 and the etching stop layer 42 can be etched down to the surface of the first metal layer 40, as shown in FIG. 14. Alternatively, the same etching process used for etching the etching stop layer 42 can be conducted by adjusting the etching selectivity of the etchant to further remove a portion of the first metal layer 40 underneath, as shown in FIG. 15. The same result can be achieved by performing an additional etching process to etch a portion of the first metal layer 40 after the second metal layer 44 and the etching stop layer 42 are removed. By either removing the etching stop layer 42 just reaching the surface of the first metal layer 40 or over-etching the etching stop layer 42, the surface of the first metal layer 40 is undisturbed by the probing process performed previously and exposed for later processes.

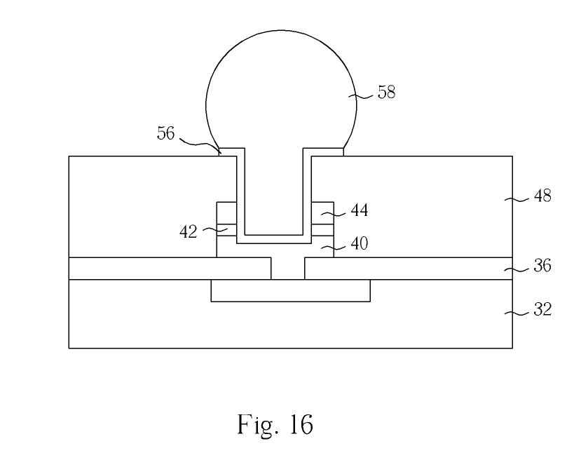

According to the preferred embodiment of the present invention, the resulting contact pad having exposed first metal layer 40 can be utilized for a wire bonding process or a bumping process. Referring to FIG. 16, FIG. 16 illustrates a perspective view of forming a bump on a contact pad according to an embodiment of the present invention. As shown in FIG. 16, after the first metal layer 40 is exposed, an under bump metallurgy layer 56 is formed on the passivation layer 48 and the exposed first metal layer 40. Subsequently, a solder is deposited into the opening above the under bump metallurgy layer 56 and a reflow process is performed to form a bump 58 on the under bump metallurgy layer 56.

In contrast to the conventional contact pad of using a single metal layer design for both probing processes and wire bonding, the present invention introduces a three-layer structure for forming a contact pad. Specifically, the contact pad of the present invention includes two metal layers and an etching stop layer therebetween. Preferably, the top metal layer can be used as a cushion for reducing the impact from the landing of a test probe during the probing process. After the probing process is completed, the top metal layer having probing tracks and disrupted surfaces and the etching stop layer are removed via an etching process to expose the bottom metal layer underneath. The exposed bottom metal layer can be used either for wire bonding or a bumping process thereafter. Since the top metal layer that carries all the damages resulted from the probing process is removed, the damage-free bottom metal layer will be able to ensure the reliability and quality of the bump and wire formed on the pad thereafter.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for forming a contact pad, comprising:
providing a substrate;
forming a conductor in the substrate;
forming a first dielectric layer on the conductor and the substrate;
forming a first opening in the first dielectric layer for exposing the conductor;
depositing a first metal layer over the surface of the first dielectric layer and in the first opening;
forming an etching stop layer on the first metal layer;
depositing a second metal layer on the etching stop layer;
patterning the second metal layer, the etching stop layer, and the first metal layer by utilizing a second dielectric layer;
depositing a passivation layer on the second metal layer and the first dielectric layer; and
forming a second opening in the passivation layer to expose a portion of the second metal layer.

2. The method for forming a contact pad of claim 1, wherein the conductor comprises a copper damascene conductor.

3. The method for forming a contact pad of claim 1 further comprising utilizing a patterned mask to form the second opening in the passivation layer.

4. The method for forming a contact pad of claim 3 further comprising utilizing the patterned mask for forming the second opening in the passivation layer to perform a first etching process for removing the second metal layer and a second etching process for removing the etching stop layer and exposing the first metal layer.

5. The method for forming a contact pad of claim 4, wherein the first etching process and the second etching process comprise in-situ etching process or an ex-situ etching process.

6. The method for forming a contact pad of claim 4, wherein the first etching process comprises a dry etching process or a wet etching process.

7. The method for forming a contact pad of claim 6, wherein the dry etching process comprises a plasma-enhanced dry etching process.

8. The method for forming a contact pad of claim 6 further comprising utilizing a phosphoric acid solution to perform the wet etching process.

9. The method for forming a contact pad of claim 4 further comprising utilizing hydrogen fluoride or regular cleaning agent (RCA) for removing the etching stop layer.

10. The method for forming a contact pad of claim 4 further comprising forming an under bump metallurgy layer on the passivation layer and the exposed first metal layer.

11. The method for forming a contact pad of claim 10 further comprising forming a bump on the under bump metallurgy layer.

12. The method for forming a contact pad of claim 3 further comprising utilizing the patterned mask for forming the second opening in the passivation layer to perform a first etching process for removing the second metal layer and a second etching process for over-etching the etching stop layer and exposing the first metal layer.

13. The method for forming a contact pad of claim 12, wherein the first etching process and the second etching process comprise in-situ etching process or an ex-situ etching process.

14. The method for forming a contact pad of claim 12, wherein the first etching process comprises a dry etching process or a wet etching process.

15. The method for forming a contact pad of claim 14, wherein the dry etching process comprises a plasma-enhanced dry etching process.

16. The method for forming a contact pad of claim 14 further comprising utilizing a phosphoric acid solution to perform the wet etching process.

17. The method for forming a contact pad of claim 12 further comprising utilizing hydrogen fluoride or regular cleaning agent (RCA) for over-etching the etching stop layer.

18. The method for forming a contact pad of claim 12 further comprising forming an under bump metallurgy layer on the passivation layer and the exposed first metal layer.

19. The method for forming a contact pad of claim 18 further comprising forming a bump on the under bump metallurgy layer.

20. The method for forming a contact pad of claim 1, wherein the second metal layer comprises a thickness of 4000 to 12000 angstroms.

21. The method for forming a contact pad of claim 1 further comprising performing a probing process on the second metal layer.

22. The method for forming a contact pad of claim 21, wherein the depth of probing process is less than the total thickness of the second metal layer and the etching stop layer.

23. The method for forming a contact pad of claim 1, wherein the first metal layer comprises aluminum, copper, tungsten, titanium, or a compound thereof.

24. The method for forming a contact pad of claim 1, wherein the etching stop layer comprises titanium, tantalum, titanium nitride, tantalum nitride or a compound thereof.

25. The method for forming a contact pad of claim 1, wherein the second metal layer comprises aluminum, copper, tungsten, titanium, or a compound thereof.

26. A contact pad, comprising:
a substrate having a conductor therein;
a first dielectric layer disposed on the conductor and the substrate, wherein the first dielectric layer comprises a first opening for exposing the conductor;
a first metal layer partially disposed over the surface of the first dielectric layer and in the first opening;
an etching stop layer disposed on the first metal layer;
a second metal layer disposed on the etching stop layer; and
a passivation layer disposed on the first dielectric layer and the second metal layer, wherein the passivation layer comprises a second opening to expose a portion of the second metal layer.

27. The contact pad of claim 26, wherein the conductor comprises a copper damascene conductor.

28. The contact pad of claim 26 further comprising a third opening in the second metal layer and the etching stop layer to expose the first metal layer, wherein the third opening is formed corresponding to the second opening of the passivation layer.

29. The contact pad of claim 28 further comprising an under bump metallurgy layer disposed on the passivation layer and the exposed first metal layer.

30. The contact pad of claim 29 further comprising a bump disposed on the under bump metallurgy layer.

31. The contact pad of claim 26, wherein the second metal layer comprises a thickness of 4000 to 12000 angstroms.

32. The contact pad of claim 26, wherein the first metal layer comprises aluminum, copper, tungsten, titanium, or a compound thereof.

33. The contact pad of claim 26, wherein the etching stop layer comprises titanium, tantalum, titanium nitride, tantalum nitride or a compound thereof.

34. The contact pad of claim 26, wherein the second metal layer comprises aluminum, copper, tungsten, titanium, or a compound thereof.
